(19) United States
(12) Patent Application Publication
(10) Pub. No.: US 2010/0102867 A1
(43) Pub. Date: Apr. 29, 2010

(54) SENSE AMPLIFIER BASED FLIP-FLOP

(76) Inventors: Sang H. Dhong, San Jose, CA (US); Gurupada Mandal, San Jose, CA (US)

Correspondence Address: MEYERTONS, HOOD, KIVLIN, KOWERT & GOETZEL (AMD), P.O. BOX 398, AUSTIN, TX, 78767-0398, US

(21) Appl. No.: 12/258,873

(22) Filed: Oct. 27, 2008

(51) Int. Cl. H03K 3/289

(52) U.S. Cl. 327/202

(57) ABSTRACT

A sense amplifier based flip-flop having built-in logic functions. The flip-flop includes a first and second input circuits configured to cause complementary first and second logic values to be provided on first and second logic nodes, respectively. The flip-flop further includes a sense circuit configured to sense and capture the first and second logic values on first and second capture nodes, respectively, during an evaluation phase, and a precharge circuit configured to precharge the first and second logic node and the first and second capture nodes during a precharge phase. The flip-flop also includes a noise immunity circuit, configured to, during the evaluation phase, become active subsequent to the sense circuit capturing the first and second logic values, wherein, when activated, the noise immunity circuit prevents floating voltages on the first and second logic nodes.

### BACKGROUND OF THE INVENTION

1. Field of the Invention

This invention relates to electronic circuits, and more particularly, to flip-flop circuits.

2. Description of the Related Art

Logic circuits are very well known in the art of electronics. Logic circuits can be divided into two main categories, combinational logic circuits and sequential logic circuits.

Combinational logic circuits include various types of common logic gates, such as AND, OR, NAND, and NOR gates. A combinational logic circuit can be a simple logic circuit having only a single gate, or can be a complex logic circuit having hundreds of gates arranged in various levels. Combinational logic circuits can be used to perform various functions such as addition, a bitwise AND or OR operation of two different operands, and so forth.

Sequential logic circuits include a wide variety of circuits whose operations depend not only on a present state of the inputs but a past state as well. One of the most common sequential circuits is the flip-flop. One type of common flip-flop edge-triggered D-type flip-flop having a master-slave configuration. Data is latched into the master portion of the flip-flop during the low portion of the clock (‘clk’) signal, with the data received on the D input propagating to the NAND gate output labeled D′. When the clock goes high, the data from D′ propagates to the output Q. Many other types of flip-flops (J-K, S R, T, etc.) are also well known in the art.

In many digital systems, the results of combinational logic operations must be propagated in a synchronous manner. This can be accomplished by coupling an output(s) of the combinational logic function to the input of a flip-flop, such as the D-type flip-flop discussed above. The result of the combinational logic function can then be conveyed by the flip-flop in a manner that is synchronous with a clock signal.

### SUMMARY OF THE INVENTION

A sense amplifier based flip-flop is disclosed. In one embodiment, a flip-flop includes a first input circuit configured to provide a first logic value on a first logic node and a second input circuit configured to provide a second logic value on a second logic node. The flip-flop further includes a sense circuit configured to sense and capture the first and second logic values on first and second capture nodes, respectively, during an evaluation phase, and a precharge circuit configured to precharge the first and second logic node and the first and second capture nodes during a precharge phase. The flip-flop further includes a noise immunity circuit, wherein the noise immunity circuit is configured to, during the evaluation phase, become active subsequent to the sense circuit capturing the first and second logic values, wherein, when activated, the noise immunity circuit prevents floating voltages on the first and second logic nodes, and wherein the noise immunity circuit is configured to be inactive during the precharge phase

In one embodiment, the noise immunity circuit is configured to cause the first and second logic nodes to be pulled to ground subsequent to the sense circuit sensing and capturing the first and second logic values. During operation of the circuit, the noise immunity circuit is inactive during the precharge phase, and becomes active during the evaluation phase. The noise immunity is coupled to receive the first and second logic values subsequent to their sensing and capture by the sensing circuit, and is activated responsive to receiving these logic values.

### BRIEF DESCRIPTION OF THE DRAWINGS

Other aspects of the invention will become apparent upon reading the following detailed description and upon reference to the accompanying drawings in which:

FIG. 1 is a block diagram of one embodiment of a sense-amplifier based flip-flop;

FIG. 2 is a schematic diagram of one embodiment of a sense-amplifier based flip-flop;

FIG. 3 is a timing diagram illustrating operation of the embodiment shown in FIG. 2;

FIG. 4 is a schematic diagram of one embodiment of a sense-amplifier based flip-flop incorporating a multiplexer function; and

FIG. 5 is a block diagram of one embodiment of an integrated circuit having a plurality incorporating a plurality of sense-amplifier based flip-flops.

While the invention is susceptible to various modifications and alternative forms, specific embodiments thereof are shown by way of example in the drawings and will herein be described in detail. It should be understood, however, that the drawings and description thereto are not intended to limit the invention to the particular form disclosed, but, on the contrary, the invention is to cover all modifications, equivalents, and alternatives falling within the spirit and scope of the present invention as defined by the appended claims.

### DETAILED DESCRIPTION OF THE INVENTION

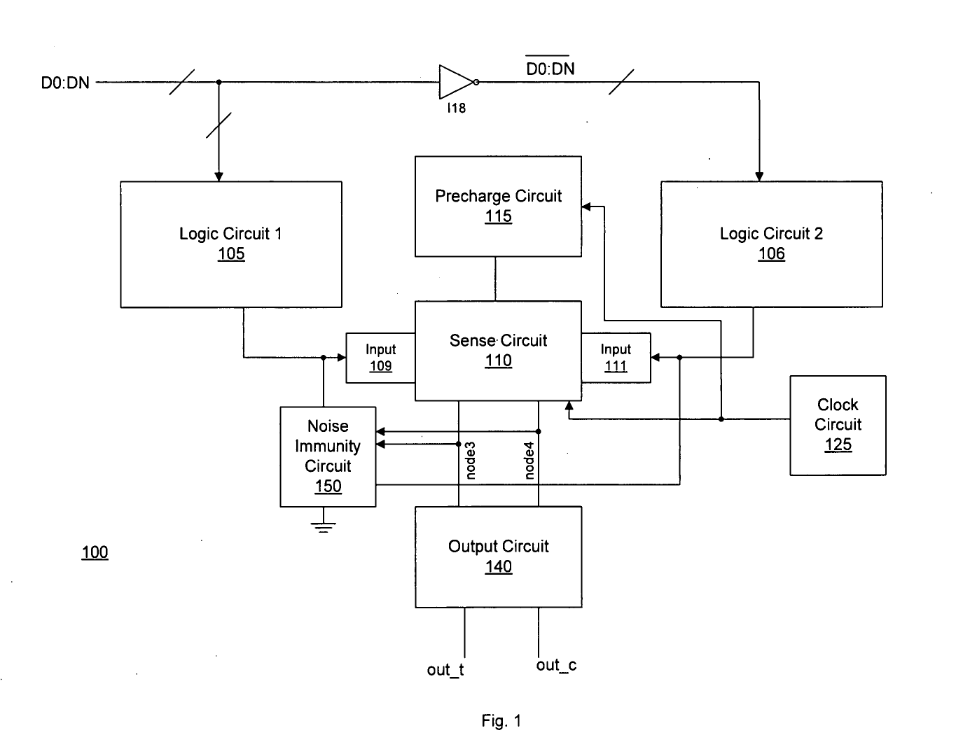

Turning now to FIG. 1, a block diagram of one embodiment of a sense-amplifier based flip-flop is shown. In the embodiment shown, flip-flop 100 includes a plurality of circuits that are depicted here as functional blocks. Each of the functional blocks perform a function which allows flip-flop 100 to operate as a sense-amplifier based flip-flop having logic functions incorporated therein.

In the embodiment shown, flip-flop 100 includes logic circuits 105 and 106. Each of these logic circuits may perform a logical function on a number of inputs D0:DN. The number of inputs may be as few as one, although as many inputs as necessary or practical may be implemented. Logical functions that may be implemented by logic circuits 105 and 106 include AND, OR, NAND, NOR, Exclusive-OR, Exclusive-NOR, invert, and so forth, as well as virtually any type of complex logic function that combines a number of different logic functions. For example, in one embodiment, each of logic circuits 105 and 106 may implement an AND-OR-Invert logic function.

The logic circuits are arranged such that logic circuit 105 and logic circuit 106 produce outputs that are complements of each other. Accordingly, in the embodiment shown, logic inputs D0:DN are provided as their true values to logic circuit 105, and as their complementary values to logic circuit 106 (via inverter circuit 118, which herein represents as many inverters as necessary for the number of logic inputs). Each of logic circuits 105 and 106 perform the same logic function, however due to the inversion of logic inputs D0:DN provided to logic circuit 106, the output thereof is a complement of the output of logic circuit 105. Embodiments where an inverter is place on the output of one of logic circuits 105 or 106 to achieve true and complementary logic outputs are also possible and contemplated.

Flip-flop 100 also includes input circuits 109 and 111. Input circuit 109 is coupled to receive a first input signal from logic circuit 105, and responsive thereto, cause a first logic value to be provided to a first logic node in sense circuit 110. Similarly, input circuit 111 is coupled to receive a second input signal from logic circuit 106, and responsive there to, cause a second logic value to be provided to a second logic node in sense circuit 110. The first and second logic values are complements of each other, as are the logic values of the first and second input signals.

In the embodiment shown, sense circuit 110 is configured to sense and capture the logic values provided to first and second logic nodes therein during an evaluation phase. More particularly, sense circuit 110 senses the logic values on the logic nodes and to capture these logic values on corresponding capture nodes. After capturing the logic values, sense circuit 110 holds these values until the precharge phase of the next cycle of operation.

Prior to the evaluation phase, flip-flop 100 may undergo a precharge phase. In the embodiment shown, precharge circuit 115 is configured to perform a precharge of various circuit nodes of sense circuit 110. The precharge may be accomplished by coupling these nodes to a supply voltage node for the duration of the precharge phase.

In the embodiment shown, clock circuit 125 is configured to provide a clock signal to both sense circuit 110 and precharge circuit 115. Depending on the state of the clock signal, flip-flop 100 may be in either the precharge phase of the evaluation phase. In this particular example, when the clock signal received from clock circuit 125 is low, flip-flop 100 operates in the precharge phase, with precharge circuit 115 performing a precharge of the nodes as described above. When the clock signal is high, flip-flop 100 operated in the evaluation phase, with sense circuit 110 sensing and capturing the logic values from logic circuit 105 and 106 on nodes 1 and 2, respectively.

Output circuit 140 is coupled to sense circuit 110 via nodes 3 and 4 in this particular embodiment, and is thus coupled to receive the logic values captured on nodes 3 and 4. These logic values are then output as true (out-t) and complementary (out-c) logic values.

The embodiment of flip-flop 100 shown in FIG. 1 also includes noise immunity circuit 150, which is configured to prevent certain internal nodes of sense circuit 110 from floating during the evaluation phase after the logic values have been captured. During the precharge phase, noise immunity circuit is inactive. During the evaluation phase, after capture of the logic values provided by the logic circuits, noise immunity circuit 150 is activated in order to prevent the floating voltages. This may be accomplished by pulling the protected nodes toward a suitable reference voltage (e.g., ground).

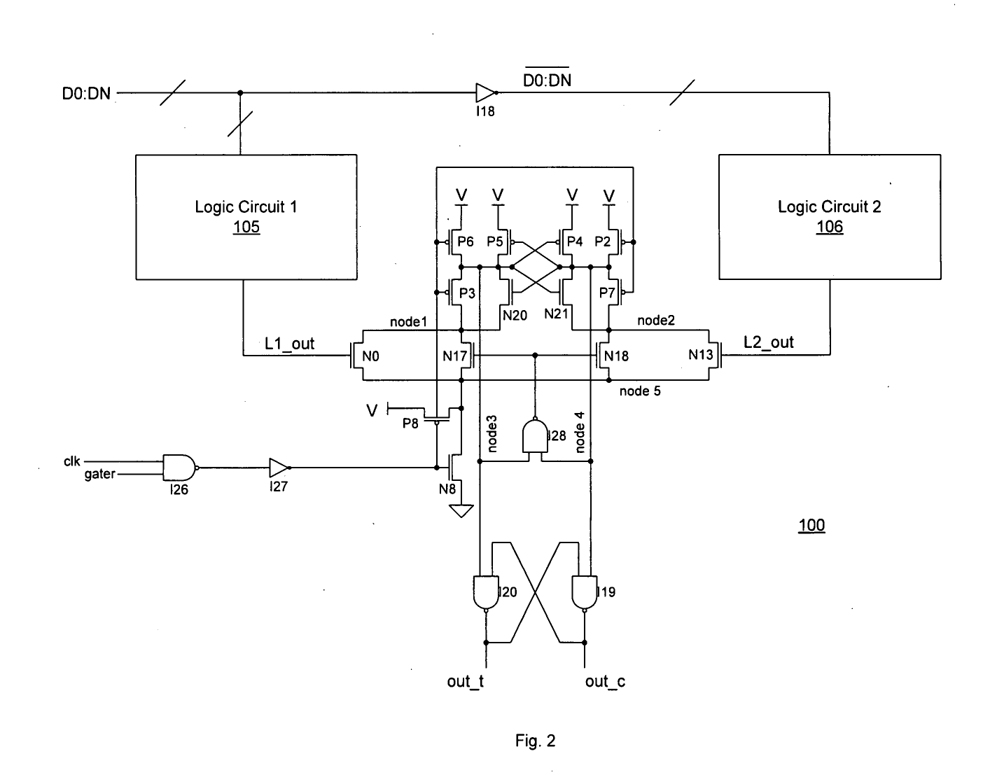

FIG. 2 is a schematic diagram of one embodiment of a sense-amplifier based flip-flop. More particularly, FIG. 2 illustrates one embodiment of a sense-amplifier based flip-flop in greater detail. In this example, logic circuits 105 and 106 are represented here as blocks, as in FIG. 1. The outputs of these logic circuits are coupled to the gates of transistors N0 and N13, which serve as the first and second input circuits, respectively, in this particular embodiment.

As a preliminary note, transistors discussed herein designated with a ‘P’ are PMOS transistors, while transistors designated with an ‘N’ are NMOS transistors. However, it is noted that the scope of the disclosure is not so limited, and that PMOS and NMOS transistors may be substituted for each other in alternate embodiments, and furthermore, that the signal polarities may also be different for other embodiments.

A precharge circuit such as the one discussed above includes transistors P2, P3, P6, P7 and P8. A sense circuit such as the one discussed above includes transistors P4, P5, N20, and N21. An output circuit such as the one discussed above includes NAND gates I19 and I20. A clock circuit such as the one discussed above includes NAND gate I26, inverter I27, and transistor N8. A noise immunity circuit such as the one discussed above includes NAND gate I28 and transistors N17 and N18.

In the embodiment shown, flip-flop 100 may be enabled through an input to the clock circuit. More particularly, the input labeled ‘gater,’ when high, enables propagation of the clock signal through the clock circuit and to transistors P8 and N8. It is the state of these two transistors that determine when this embodiment of flip-flop 100 is operating in the precharge phase or the evaluation phase.

In this example, the precharge phase occurs when the clock signal is low. When the clock signal is low, transistor N8 is turned off, while transistors P2, P3, P6, P7, and P8 (i.e. the transistors of the precharge circuit) are all turned on. When these transistors are active, nodes 1 through 5 are pulled up toward voltage V. Node 1 is pulled toward voltage V through transistors P3 and P6, while node 2 is pulled toward voltage V through transistors P2 and P7. Nodes 3 and 4 are pulled toward voltage V through transistors P2 and P6, respectively. Node 5 is pulled toward voltage V through transistor P8, regardless of the state of transistors NO and N13. Pulling these nodes toward voltage V precharges these nodes to a voltage that is at or near that of voltage V.

When the clock transitions high, the embodiment shown exits the precharge phase and enters the evaluation phase. When the clock signal is high, the transistors of the precharge circuit are turned off, while transistor N8 is turned on. When transistor N8 is turned on, node 5 is discharged through this transistor and thereby pulled toward ground. Furthermore, since logic circuits 105 and 106 are configured to provide true and complementary logic outputs on nodes L1_out and L2_out, respectively, one of nodes 1 or 2 will also discharge. If logic circuit 105 produces a logic high output, transistor NO will turn on, and node 1 will discharge through this transistor and transistor N8, thereby causing a logic low value on node 1. Since transistor N13 remains turned off in this scenario, it effectively causes a logic high value on node 2, as a result of it remaining off subsequent to the precharge.

If logic circuit 106 produces a logic high output in this embodiment, transistor N13 will turn on and allow node 2 to discharge through this transistor and transistor N8, thereby causing a logic low value on node 2. Since transistor N0 remains off in this scenario, it effectively causes a logic high value on node 1, since it remains off subsequent to the precharge.

When the evaluation phase begins in this particular embodiment, both transistors N20 and N21 are turned on. Thus, when one of nodes 1 or 2 fall low, one of nodes 3 or 4 will fall low as a result. If node 1 falls low, node 3 is pulled low (toward ground) through transistors N20, N0, and N8. If node 2 falls low, node 4 is pulled low (toward ground) through transistors N21, N13, and N8. Pulling one of nodes 3 or 4 toward ground will, in turn, cause one of transistors N20 or N21 to turn off, as well as causing one of transistors P4 or P5 to turn on. If node 3 falls low, transistor P4 turns on while transistor N21 turns off. Turning on transistor P4 while turning off transistor N21 in effect captures a logic high value on node 4 by pulling it up toward voltage V. Furthermore, the high on node 4 further ensures that transistor N20 will remain turned one while transistor P5 will remain turned off. Thus, a logic low is captured on node 3 and a logic high is captured on node 4 in this example.

If, in the embodiment shown, the logic values present on nodes 1 and 2 are reversed (i.e. a logic low on node 2 and a logic high on node 1), transistor P5 will be turned on while transistor N20 will be turned off. Furthermore, transistor P4 will be turned off while transistor N21 will be turned on (as a result of the logic high on node 3). Thus, a logic high value is captured on node 3, while a logic low value is captured on node 4.

As previously noted, the embodiment shown in FIG. 2 includes a noise immunity circuit that includes transistor N17, N18, and NAND gate I28. At the end of the precharge phase, both nodes 3 and 4 are at a logic high value. NAND gate I28 includes two inputs, one from node 3 and one from node 4. Thus, when both nodes 3 and node 4 are at a logic high value, the output of NAND gate I28 is a logic low value. Accordingly, transistors N17 and N18 are turned off when both nodes 3 and 4 are at a logic high value. During the evaluation stage, a logic high value is captured on one of nodes 3 or 4, while a logic low value is captured on the other one of these nodes. Thus, one of the inputs to NAND gate I28 will be a logic low value, while the other is a logic high value, causing the output of 128 to transition to a logic high value. As a result, both transistors N17 and N18 will turn on, providing a path to pull nodes 1 and 2, respectively, toward ground (i.e. through N17/N18 and N8). Pulling these two nodes down prevents floating voltages, which might otherwise occur on one of nodes 1 or 2 if such an embodiment was lacking the noise immunity circuit that includes these transistors.

It is important to note the timing relationships in the embodiment of FIG. 2. At the end of the precharge phase, nodes 1, 2, 3, and 4 are all in a logic high state. When one of nodes 1 or 2 falls low after entering the evaluation phase, the corresponding one of nodes 3 or 4 will also fall low. If node 3 falls low (as a result of node 1 falling low) transistor N21 will be turned off. Similarly, if node 4 falls low (as a result of node 2 falling low), transistor N20 will be turned off. As a result of one of nodes 3 or 4 falling low, the output of NAND gate I28 will transition high, which results in transistors N17 and N18 both being turned on, and both of nodes 1 and 2 falling low. Thus, in the embodiment shown, transistors N20 and N21 are designed such that, during the evaluation phase, they will turn off before transistors N17 and N18 turn on, thereby ensuring the appropriate one of nodes 3 or 4 captures and maintains a logic high value. Ensuring sufficient gate delay in NAND gate I28 and/or implementing transistors N20 and N21 so that they have a faster switching time than transistors N17 and N18 may accomplish this timing relationship. However, any suitable means of ensuring the necessary delay between the capturing of logic values and activating the noise immunity circuitry may be used in implementing various embodiments of the sense-amplifier based flip-flop.

In the embodiment shown, nodes L1_out and L2_out do not need to hold their states for the entirety of the evaluation phase. Instead, these nodes need only to hold their states until the sense circuit has evaluated and captured the correct logic values on the capture nodes, nodes 3 and 4. For example, assume that L1_out is a logic 0 and L2_out is a logic 1. After evaluation, the sense circuit will capture a logic 1 on node 3 and a logic 0 on node 4. As a result of the logic values captures on nodes 3 and 4, transistors N21 and P5 will be turned on, while transistors N2 and P4 will be turned off. It is also assumed, for the sake of this example, assume that the logic values present on L1_out and L2_out change states to a logic 1 and a logic 0, respectively, subsequent to the capture of the logic values on nodes 3 and 4. If this were to occur in an embodiment without the noise immunity circuit described herein, node 2 would be floating, and node 4 (originally holding a captured logic 0) would no longer have a path to ground. As a result, node 4 would also float, and might be unable to hold a value of logic 0 during low frequency operation. By implementing the noise immunity circuit using NAND gate I28 and transistors N17 and N18, it is guaranteed that both of these transistors will turn on and will provide a path to ground for node 4, on which a logic 0 was captured in this example (the same applies for the situation if a logic 0 was captured on node 3, i.e. the noise immunity circuit will provide a path to ground). The path to ground provided to one of the capture nodes by transistors N17 or N18 ensure that the one of capture nodes 3 or 4 evaluated at a logic 0 will be able to maintain this value even if one or both of nodes L1_out and L2_out change states.

The solution provided by the noise immunity circuit, as exemplified above, may be more effective than solutions wherein a transistor, such as a weak, permanently on NMOS transistor, is coupled between nodes 1 and 2, as such a solution typically provides a DC path that in turn allows a DC current to flow between these nodes. Furthermore, transistors N17 and N18 can be configured to have a pull capability that is as strong as transistors N0 and N13. This may in turn provide a stronger pulldown to ground on nodes 1, 2, 3, and 4 when circuit operation necessitates these nodes be pulled to ground, thereby making the overall circuit more resilient.

The output values captured by nodes 3 and 4 are conveyed to corresponding inputs of NAND gates I20 and I19, respectively, which form the output circuit for the example shown in FIG. 2. These cross-coupled NAND gates are configured such that they may hold the previous output states until new inputs are received. That is, during the precharge phase, the logic values present on output out-t and out-c are those from the previous clock cycle. During the evaluation phase, the true and complementary outputs follow the state of the outputs from logic circuits 105 and 106, respectively. That is, the output out_t will be the same logic value as the output from logic circuit 105 received at the gate of transistor N0, while the output out_c will be the same logic value as the output IS of logic circuit 106, received at the gate of transistor N13.

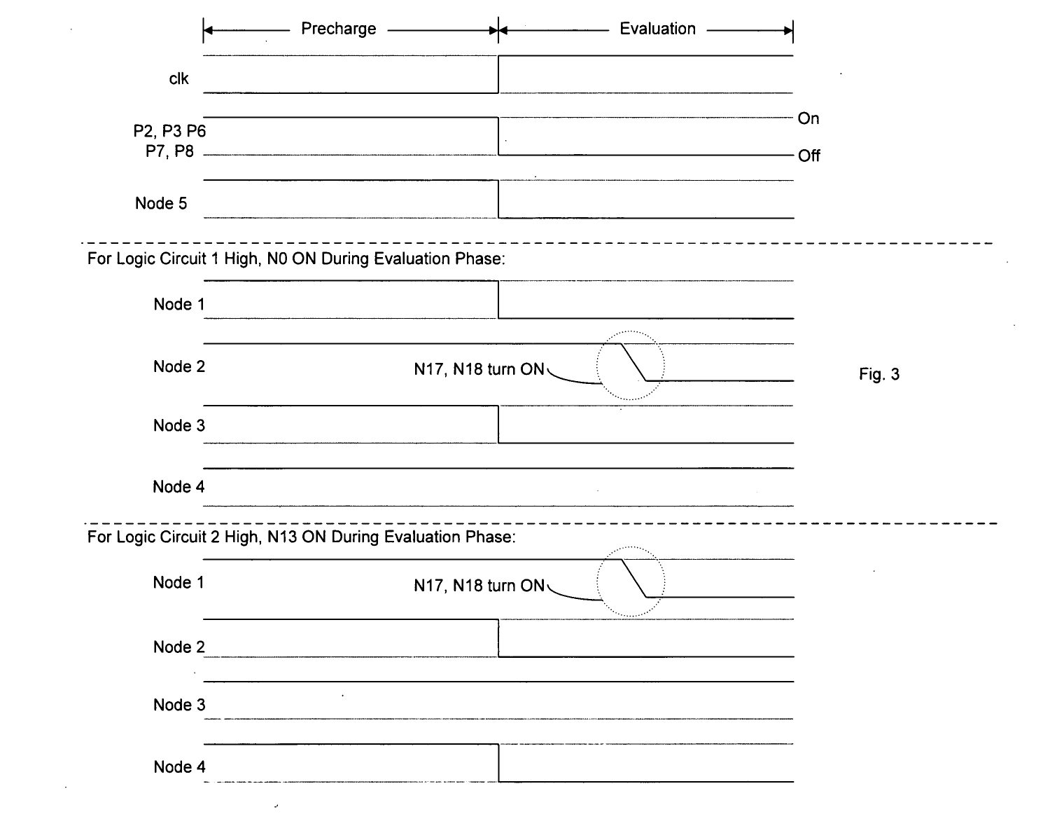

The operation of the circuit embodiment shown in FIG. 2 is further illustrated by the timing diagram of FIG. 3. It is noted that for mnemonics shown in the timing diagram, the levels alternate between a high and a low voltage, with the exception of the mnemonic referring to transistors P2, P3, and P6-P8, which alternate between ON and OFF.

The operation of the embodiment shown in FIG. 2 can be divided into a precharge phase, when the clock signal (‘clk’) is low, and an evaluation phase, when the clock signal is high. Transistors P2, P3, and P6-P8 are turned on during the precharge phase, thereby enabling a precharge of nodes 1-5. For an cycle in which the operation of logic circuit 1 includes a logic high value on transistor N0, node 1 falls low responsive to the beginning of the evaluation phase. Node 3 thus falls low responsive to node 1 falling low. Node 4 is captured as a logic high value during the evaluation phase. Since the values of nodes 3 and 4 are no longer the same, the output of NAND gate I28 will transition high, causing transistors N17 and N18 to turn on. This results in node 2 falling low, as shown in the drawing. The exact point in time that this occurs within the evaluation phase may vary from one embodiment to the next. The only requirement for implementing the circuit is to allow sufficient time for the logic high value to be captured on node 4. This requirement may be satisfied by the gate delay of I28 and the turn-on delay of transistors N17 and N18.

Operation of the circuit of FIG. 2 in which the operation of logic circuit 1 includes a logic high value on transistor N13 is similar to that as described in the previous paragraph. However, the signal states of nodes 1 and 2 are reversed (e.g., node 2 falls low responsive to entering the evaluation phase) as are the signal states of nodes 3 and 4 (e.g., node 4 falls low responsive to node 2 falling low).

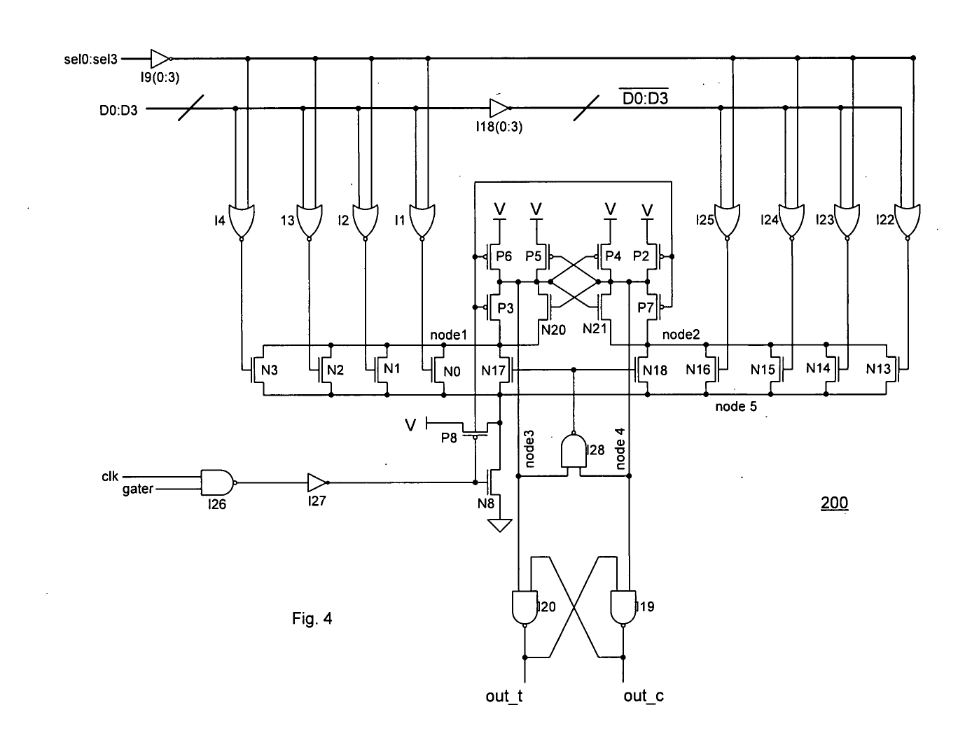

Turning now to FIG. 4, a schematic diagram of one embodiment of a sense-amplifier based flip-flop incorporating a multiplexer function. The embodiment shown in FIG. 4 is similar to that of FIG. 2, although in this particular example, flip-flop 200 incorporates a multiplexer function. A first logic circuit is a first multiplexer implemented via NOR gates I1-I4. A second logic circuit is a second multiplexer implemented via NOR gates I22-I25, and is configured to provide an output value that is the complement of the first multiplexer. A first input circuit includes transistors N0, N1, N2, and N3, while a second input circuit includes transistors N13, N14, N15, and N16. Flip-flop 200 also includes first inverter circuitry I9, to invert each of select inputs sel0:sel3 as provided to the NOR gates of both logic circuits, and second inverter circuitry I18, to invert the data inputs D0:D3 as provided to the NOR gates I22-I25. It is noted that single signal lines and single inverter symbols are shown in FIG. 4 as corresponding to data inputs D0:D3 and select inputs sel0:sel3. However, it is to be understood that these are representative of bussed signals, with separate signal lines and separate inverters for each of the data inputs and select inputs.

Based on the data inputs and the select inputs, one of transistors N0-N3 or one of transistors N13-N16 will turn on during the evaluation phase, thereby causing the corresponding one of node 1 or 2 to fall low. The operation of the sense circuitry, precharge circuitry, output circuitry, and noise-immunity circuitry may be largely similar to that of the embodiment shown in FIG. 2.

As noted, the example shown in FIG. 4 incorporates the logic function of a multiplexer into flip-flop 200. Numerous other possible embodiments exist in which different types of logic functions are implemented. A logic circuit as disclosed herein can be as simple as a buffer function or an inverter function. Other logic functions that may be incorporated into a flip-flop in accordance with this disclosure include inverters, various gates such as AND, OR, NAND, NOR, and so forth, as well as various combinations thereof. Furthermore, the disclosure herein does not limit the number of, types of, or various combinations of logic circuits that may be incorporated into various embodiments of the flip-flop described above. It is also noted that embodiments are possible and contemplated wherein no logic function is implemented, and thus, wherein the flip-flop functions similar to a D-type flip-flop, where the output values follow corresponding input values (i.e. the true output value is the same as the true input value, the complementary output value is the same as the complementary input value).

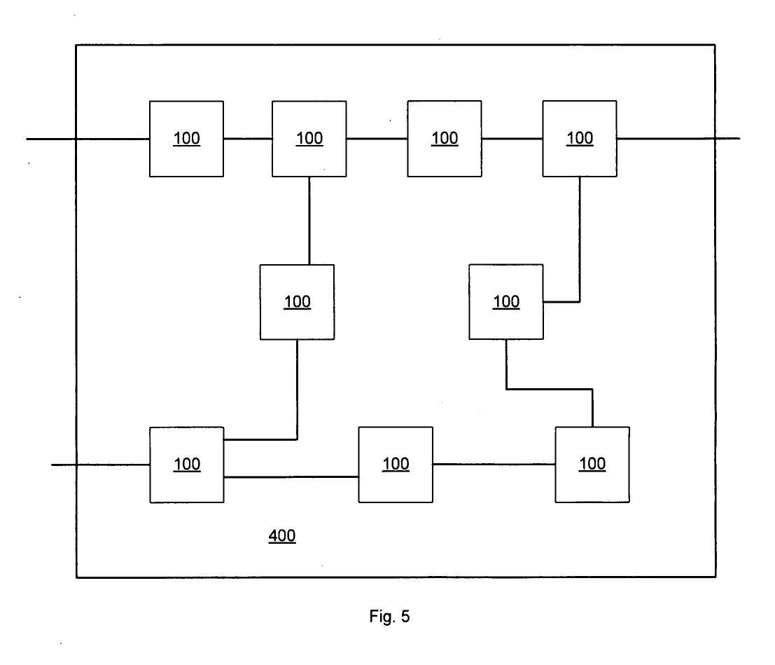

FIG. 5 is a block diagram of one embodiment of an integrated circuit having a plurality incorporating a plurality of sense-amplifier based flip-flops. In the embodiment shown, integrated circuit 400 includes a plurality of flip-flops 100 coupled to form various data paths. Integrated circuit 400 may include other circuitry not shown here for the sake of simplicity. Flip-flops 100 shown in FIG. 5 are flip-flops that incorporate logic functions, such as those discussed above with reference to FIGS. 1-4. The flip-flops 100 shown in this example need not all incorporate the same logic functions. Furthermore, as noted above, the logic functions incorporate may vary from the simple to the complex, incorporating as little as a single transistor, numerous gates and/or combinations thereof, or any level of complexity in between.

Flip-flops 100 according to this disclosure may be implemented in a wide variety of electronic devices, such as microprocessors, digital signal processors, chipsets, various types of chips for transmitting, receiving, and/or converting data between various formats, and so forth. In general, flip-flops according to this disclosure may be implemented in any environment wherein it is necessary to perform logic functions and to synchronize the outputs of these logic functions with a clock.

While the present invention has been described with reference to particular embodiments, it will be understood that the embodiments are illustrative and that the invention scope is not so limited. Any variations, modifications, additions, and improvements to the embodiments described are possible. These variations, modifications, additions, and improvements may fall within the scope of the inventions as detailed within the following claims.

What is claimed is:

1. An electronic circuit comprising:
a first input circuit coupled to receive a first input signal and configured to cause a first logic value to be provided, during an evaluation phase, on a first logic node responsive to the first input signal;
a second input circuit coupled to receive a second input signal and configured to cause a second logic value to be provided on a second logic node, during the evaluation phase, responsive to the second input signal, the second logic value being a complement of the first logic value;
a sense circuit configured to sense and capture the first and second logic values on first and second capture nodes, respectively, during the evaluation phase;
a precharge circuit configured to precharge the first and second logic node and the first and second capture nodes during a precharge phase; and
a noise immunity circuit, wherein the noise immunity circuit is configured to, during the evaluation phase, become active subsequent to the sense circuit capturing the first and second logic values, wherein, when activated, the noise immunity circuit prevents floating voltages on the first and second logic nodes, and wherein the noise immunity circuit is configured to be inactive during the precharge phase.

2. The electronic circuit as recited in claim 1, wherein the noise immunity circuit is configured to cause the first and second logic nodes to be pulled toward a reference voltage subsequent to the sense circuit sensing and capturing the first and second logic values.

3. The electronic circuit as recited in claim 2, wherein the noise immunity circuit is configured to be inactive during the precharge phase, and wherein the noise immunity circuit is further configured to become active subsequent to entering the evaluation phase.

4. The electronic circuit as recited in claim 3, wherein the noise immunity circuit is coupled to receive the first and second logic values from the sense circuit during the evaluation phase.

5. The electronic circuit as recited in claim 4, wherein the noise immunity circuit is configured to be activated responsive to receiving the first and second logic values.

6. The electronic circuit as recited in claim 1, wherein the electronic circuit is configured to receive a clock signal having a clock cycle, wherein the circuit is configured to operate in the precharge phase during a first portion of a clock cycle and operate in the evaluation phase during a second portion of the clock cycle, wherein the clock signal is low during the first portion of the clock cycle and wherein the clock signal is high during a second portion of the clock cycle.

7. The electronic circuit as recited in claim 6, further comprising a clock circuit, wherein the clock circuit is coupled to provide the clock signal to the precharge circuit and the sense circuit.

8. The electronic circuit as recited in claim 1, wherein the electronic circuit includes:
an output circuit configured to provide, as output, the first and second logic values;
a first logic circuit configured to perform a first logic function and provide a first input signal to the first input circuit; and
a second logic circuit configured to perform a second logic function and provide a second input signal to the second logic circuit.

9. An integrated circuit comprising:
a plurality of logic circuits, wherein the plurality of logic circuits includes one or more sense-amplifier based flip-flops each having built-in logic functions, wherein each of the one or more sense-amplifier based flip-flops includes:
a first input circuit coupled to receive a first input signal and configured to cause a first logic value to be provided on a first logic node responsive to the first input signal during an evaluation phase;
a second input circuit coupled to receive a second input signal and configured to cause a second logic value to be provided on a second logic node, during the evaluation phase, responsive to the second input signal, the second logic value being a complement of the first logic value;
a sense circuit configured to sense and capture the first and second logic values on first and second capture nodes, respectively, during the evaluation phase;
a precharge circuit configured to precharge the first and second logic node and the first and second capture nodes during a precharge phase; and
a noise immunity circuit, wherein the noise immunity circuit is configured to, during the evaluation phase, become active subsequent to the sense circuit capturing the first and second logic values, wherein, when activated, the noise immunity circuit prevents floating voltages on the first and second logic nodes and wherein the noise immunity circuit is configured to be inactive during the precharge phase.

10. The integrated circuit as recited in claim 9, wherein the noise immunity circuit is configured to cause the first and second logic nodes to be pulled toward a reference voltage subsequent to the sense circuit sensing and capturing the first and second logic values.

11. The integrated circuit as recited in claim 10, wherein the noise immunity circuit is configured to be inactive during the precharge phase, and wherein the noise immunity circuit is configured to become active subsequent to entering the evaluation phase.

12. The integrated circuit as recited in claim 11, wherein the noise immunity circuit is coupled to receive the first and second logic values from the sense circuit during the evaluation phase.

13. The integrated circuit as recited in claim 12, wherein the noise immunity circuit is configured to be activated responsive to receiving the first and second logic values.

14. The integrated circuit as recited in claim 9, wherein the electronic circuit is configured to receive a clock signal having a clock cycle, wherein the circuit is configured to operate in the precharge phase during a first portion of a clock cycle and operate in the evaluation phase during a second portion of the clock cycle, wherein the clock signal is low during the first portion of the clock cycle and wherein the clock signal is high during a second portion of the clock cycle.

15. The integrated circuit as recited in claim 14, wherein the flip-flop includes comprising a clock circuit, wherein the clock circuit is coupled to provide the clock signal to the precharge circuit and the sense circuit.

16. The integrated circuit as recited in claim 9, wherein the flip-flop further includes: an output circuit configured to provide, as output, the first and second logic values;
a first logic circuit configured to perform a first logic function and provide logic first logic value to the first input circuit; and
a second logic circuit configured to perform a second logic function and provide the second logic value to the second logic circuit.

17. An electronic circuit comprising:
first means for receiving a first input signal and causing a first logic value to be provided on a first logic node during an evaluation phase, responsive to the first input signal;
second means for receiving a second input signal and causing a second logic value to be provided, during the evaluation phase, on a second logic node responsive to the second input signal, the second logic value being a complement of the first logic value;
third means for sensing and capturing the first and second logic values on first and second capture nodes, respectively, during the evaluation phase;
fourth means for precharging the first and second logic nodes and first and second capture nodes during a precharge phase; and
fifth means for preventing floating voltages on the first and second logic nodes during the evaluation phase subsequent to said third means sensing and capturing the first and second logic values from the first and second logic nodes, respectively, wherein said fifth means is inactive during said precharge phase.

18. The electronic circuit as recited in claim 17, wherein said fifth means is inactive during the precharge phase and becomes active during the evaluation phase.

19. The electronic circuit as recited in claim 18, wherein said fifth means is activated responsive to receiving the first and second logic values from said third means, wherein said fifth means pulls the first and second logic nodes towards a reference voltage responsive to activation.

20. The electronic circuit as recited in claim 17 further comprising:
sixth means for gating a clock signal and providing the clock signal to said third means and said fourth means, wherein the clock signal, when low, causes said electronic circuit to enter the precharge phase, and wherein the clock signal, when high, causes said electronic circuit to enter the evaluation phase;
seventh means for receiving the first and second logic values from said third means and for providing said first and second logic values as outputs from the electronic circuit;
eighth means for performing a first logic function to generate the first input signal; and
ninth means for performing a second logic function to generate the second input signal, the first and second input signals being logic signals having logic values that are complements of each other.
